(19) United States
(12) Patent Application Publication
(10) Pub. No.: US 2025/0006734 A1
(43) Pub. Date: Jan. 2, 2025

(54) PERFORMANCE OPTIMIZATION OF TRANSISTORS SHARING CHANNEL STRUCTURES OF VARYING WIDTH

(71) Applicant: Intel Corporation, Santa Clara, CA (US)

(72) Inventors: Tao Chu, Portland, OR (US); Minwoo Jang, Portland, OR (US); Yanbin Luo, Portland, OR (US); Paul Packan, Hillsboro, OR (US); Guowei Xu, Portland, OR (US); Chiao-Ti Huang, Portland, OR (US); Robin Chao, Portland, OR (US); Feng Zhang, Hillsboro, OR (US); Ting-Hsiang Hung, Beaverton, OR (US); Chia-Ching Lin, Portland, OR (US); Yang Zhang, Rio Rancho, NM (US); Chung-Hsun Lin, Portland, OR (US)

(73) Assignee: Intel Corporation, Santa Clara, CA (US)

(21) Appl. No.: 18/216,493

(22) Filed: Jun. 29, 2023

(51) Int. Cl. H01L 27/092; H01L 29/06; H01L 29/10; H01L 29/423; H01L 29/775; H01L 29/78

(52) U.S. Cl. CPC H01L 27/092; H01L 29/0673; H01L 29/1037; H01L 29/42392; H01L 29/775; H01L 29/7845; H01L 29/7851

(57) ABSTRACT

An integrated circuit (IC) device includes a stripe of material perpendicular to, and spanning between, semiconductor structures with multiple widths, and the stripe is between transistors with channel regions of differing widths in the semiconductor structures. The material stripes cover transition portions between different widths of the semiconductor structures. The semiconductor structures may be channel structures of different types, including groups of fins or nanoribbons. Channel regions of differing widths may include more or fewer fins or narrower or wider nanoribbons. The channel regions may have alternating conductivity types, n- and p-type.

### BACKGROUND

Devices may be more readily designed to have improved performance, provide increased power, or use less area with the design flexibility of deploying adjacent transistors with varying channel widths. Optionally employing a range of channel widths allows transistors of optimal size and conductance to be appropriately utilized. Transistors of different sizes are generally fabricated in disparate die locations or, if co-located, consume extra die area or suffer reduced performance. Routing inefficiencies may be added, and corresponding performance degradations introduced, when using non-adjacent transistors in a same circuit.

Improved structures and materials are needed to enable deployment, and optimize performance, of adjacent transistors of varying sizes.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A and 1B illustrate plan and cross-sectional profile views of a device having conductive floating structures over an array of transistors and shared semiconductor channel structures with channel regions of varying widths, in accordance with some embodiments;

FIGS. 2A, 2B, 2C, 2D, and 2E illustrate plan and cross-sectional profile views of an integrated circuit (IC) device having a conductive floating structure over, and coupled to, channel regions within fins of a semiconductor channel structure, in accordance with some embodiments;

FIG. 3 illustrates a plan view of an IC device having conductive floating structures over an array of transistors and shared semiconductor channel structures with channel regions of varying widths, in accordance with some embodiments;

FIGS. 4A, 4B, 4C, 4D, and 4E illustrate plan and cross-sectional profile views of an IC device having a conductive floating structure over, and coupled to, channel regions within nanoribbons of a semiconductor channel structure, in accordance with some embodiments;

FIGS. 5A, 5B, 5C, 5D, and 5E illustrate plan and cross-sectional profile views of an IC device having a conductive floating structure over, and coupled to, channel regions within nanoribbons of a semiconductor channel structure, in accordance with some embodiments;

FIG. 6 illustrates a diagram of an example data server machine employing an IC device having channel structures with multiple widths and having performance-optimizing structures spanning the channel structures, in accordance with some embodiments; and

FIG. 7 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected.” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve the performance of integrated circuit (IC) devices with transistors sharing channel structures with varying widths. Power, performance, and area advantages may be achieved by adjacently deploying transistors of differing sizes. The ability to use optimally sized transistors for desired applications without inefficient and excessive routing restrictions provides valuable design flexibility.

However, co-locating transistors of different channel widths may introduce new difficulties, such as elevated threshold voltages Vth, which result in reduced drive currents and degraded performance over frequency.

New structures are introduced which may restore or improve device performance without added cost. Material stripes, such as of conductors, may be spanned over channel structures between channel regions and transistors to engineer optimal strains in semiconductor channels. The stripes may be floating structures that increase device performance without drawing further currents away from transistors. The floating structures may be manufactured concurrently with, and in a same fashion as, gate structures, but deployed between channel regions and transistors rather than over channels in transistors. The floating structures, like gate stacks, may include a conductor (such as a metallization structure) coupled to (but separated from) a channel structure by an insulator, such as a dielectric layer. The dielectric layer may be the same material as a gate dielectric layer, but deployed as isolation between the floating conductor (not contacted) and the channel structures.

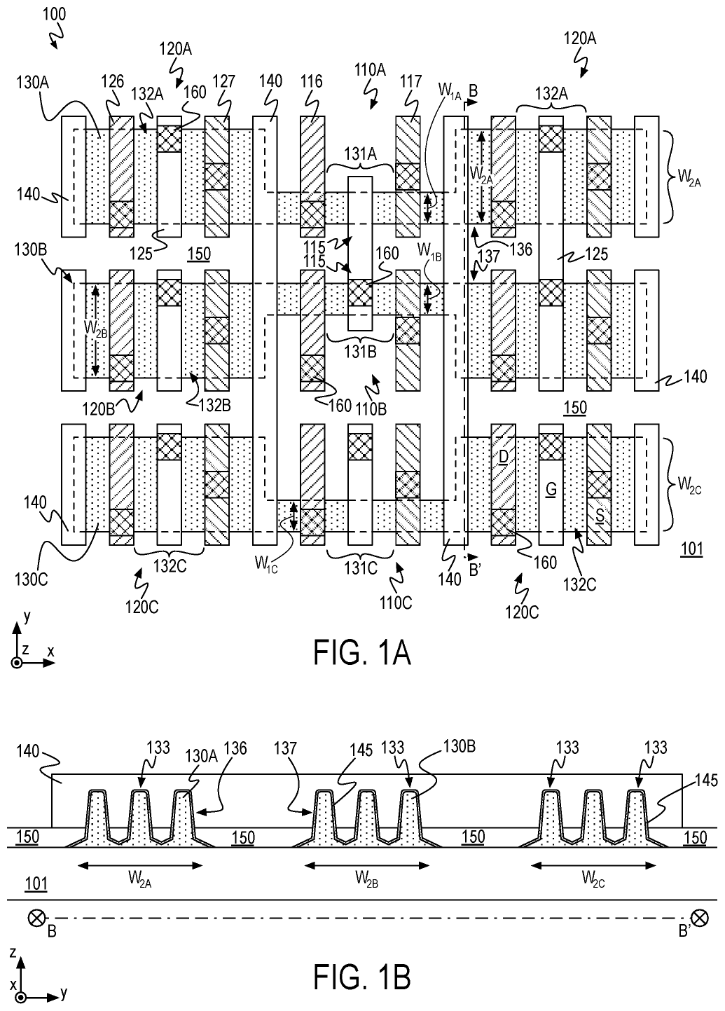

FIGS. 1A and 1B illustrate plan and cross-sectional profile views of a device 100 having conductive floating structures 140 over an array of transistors 110, 120 and shared semiconductor channel structures 130 with channel regions 131, 132 of varying widths W₁, W₂, in accordance with some embodiments. Semiconductor channel structures 130 extend through, and are shared by, transistors 110, 120 with channel regions 131, 132 of varying widths W₁, W₂. Conductive floating structures 140 couple to multiple channel structures 130, over (and extending in a direction perpendicular to a direction of) channel structures 130. Isolation structures 150 are between channel structures 130 (e.g., between sidewalls 136, 137 of channel structures 130), and structures 150 separate channel structures 130 and corresponding transistors 110, 120 from other channel structures 130 and transistors 110, 120. Conductive floating structures 140 extend over isolation structures 150. FIG. 1A shows a plan view of device 100, including a dashed line indicating the cross-sectional view B-B′. FIG. 1B illustrates a profile of device 100 at cross-sectional view B-B′ through conductive floating structure 140 and multiple channel structures 130.

The presence of conductive floating structures 140 may effect a beneficial adjustment of threshold voltages Vₜₕ. For example, floating structures 140 may shift threshold voltage Vₜₕ downward (relative to a device without floating structures 140) and so increase drive current and improve frequency response. Advantageously, floating structures 140 may substantially align threshold voltage Vₜₕ for transistors 110, 120 (e.g., with each other, as well as other transistors (not shown) in device 100, including transistors having channel regions included in other channel structures, with or without width jogs). In some embodiments, aligned threshold voltages Vₜₕ for may enable optimal performance, e.g., for circuits requiring balanced or synchronized operation of various switching devices (such as logic or timing gates). Characteristics of the threshold voltage Vₜₕ adjustment, e.g., a magnitude, may be controlled by adjustments of floating structure(s) 140, such as a size or span of floating structure(s) 140. For example, a longer floating structure 140 (e.g., spanning further over one or more channel structures 130) may have the effect of more closely aligning threshold voltages Vₜₕ of transistors 110, 120 (with those channel regions 131, 132 in channel structures 130 coupled by floating structure 140) with other device threshold voltages Vₜₕ.

Device 100 includes semiconductor channel structures 130 (referenced as structures 130A, 130B, 130C), extending in the x direction beyond floating structures 140. In FIGS. 1A and 1B, some elements (such as transistors 110, 120) are referenced according to the corresponding structure 130A, 130B, 130C (e.g., as transistors 110A, 120A coupled to semiconductor channel structure 130A). For example, semiconductor structure 130A includes a first channel region 131A with a first width W_{1A} and a second channel region 132A with a second width W_{2A} greater than width W_{1A}. Semiconductor structure 130B includes channel region 131B with width W_{1B} and channel region 132B with width W_{2B} greater than width W_{1B}. Semiconductor structure 130C includes channel region 131C with width W_{1C} and channel region 132C with width W_{2C} greater than width W_{1C}. Transistors 110 include channel regions 131 with widths W₁, and transistors 120 include channel regions 132 with widths W₂. In some embodiments, semiconductor channel structures 130A, 130B, 130C have different widths W_{1A}, W_{1B}, W_{1C}. In some embodiments, semiconductor channel structures 130A, 130B, 130C have different widths W_{2A}, W_{2B}, W_{2C}.

Device 100 includes floating structures 140, which are stripes of material extending in the y direction (perpendicular to the x direction) and coupling semiconductor structures 130A, 130B, 130C. Floating structures 140 extend over and couple semiconductor structures 130 between channel regions 131, 132 and transistors 110, 120. Channel regions 131 are between floating structures 140. In some embodiments, floating structures 140 are conductive structures (e.g., of a metal) not electrically coupled (for example, by a metal or other conductive line) to conductive structures electrically coupled to ground, a power supply voltage, or another electrical node driven to a voltage by electrical coupling by one or more conductors or semiconductor device(s). Floating structures 140 are referred to as “floating” conductors because floating structures 140 are isolated or insulated from other conductive and/or conducting structures. Floating structures 140 may be a high-impedance node, and any voltage on such a “floating” node may be an undetermined (or difficult to determine, e.g., model) voltage relative to nodes tied or electrically coupled by low-impedance paths (e.g., conductors or conducting semiconductor devices) to ground or a power supply voltage.

In the exemplary embodiment, transistor 110A has a first threshold voltage Vₜₕ₁ₐ, transistors 120A have a second threshold voltage Vₜₕ₂ₐ, and threshold voltages Vₜₕ₁ₐ, Vₜₕ₂ₐ are substantially equal. For example, threshold voltage Vₜₕ₁ₐ may be 20 mV greater than threshold voltage Vₜₕ₂ₐ, which may be considered substantially equal. In devices with similar structures except without floating structures 140, threshold voltage Vₜₕ₁ₐ may be 21 mV greater than threshold voltage Vₜₕ₂ₐ, which is not substantially equal. In the exemplary embodiment, transistor 110B has a first threshold voltage V_{th1b}, transistors 120B have a second threshold voltage V_{th2b}, and threshold voltages V_{th1b}, V_{th2b} are substantially equal. In the exemplary embodiment, transistor 110C has a first threshold voltage V_{th1c}, transistors 120C have a second threshold voltage V_{th2c}, and threshold voltages V_{th1c}, V_{th2c} are substantially equal. In some embodiments, transistors 110A, 110B, 110C, 120A, 120B, 120C have substantially equal threshold voltages Vₜₕ₁ₐ, Vₜₕ₂ₐ, V_{th1b}, V_{th2b}, V_{th1c}, V_{th2c}, which are substantially equal to threshold voltages Vₜₕ of other transistors in device 100, e.g., with channel regions included in semiconductor channel structures without multiple widths.

Device 100, including the array of transistors 110, 120 and channel structures 130, is in or on substrate 101. Substrate 101 may be, for example, an IC die or wafer, and may be of any suitable material or materials. The substrate may include a semiconductor or insulator material, including a crystalline material. In some embodiments, the substrate includes monocrystalline silicon (Si), germanium (Ge), silicon germanium (SiGe), a III-V alloy material (e.g., gallium arsenide (GaAs)), a silicon carbide (e.g., SiC), a sapphire (e.g., Al₂O₃), or any combination thereof. Substrate 101 may also include other semiconductor materials, metals, dielectrics, dopants, and other materials commonly found in semiconductor substrates. Transistors 110, 120 may be at a same level as, above, or below other such devices and/or other transistors in or on substrate 101. For example, device 100 may be beneath or within interconnect layers in a processor of an IC device. Device 100 may be in a front- or backside of substrate 101. Substrate 101 may include various dielectrics, including low-permittivity (“low-K”) dielectrics, such as an inter-metal dielectric (IMD) or an inter-layer dielectric (ILD), e.g., an etch-stop layer, hermetic seal, etc., that isolate various conductive elements (e.g., conductive floating structures 140). Isolation structures 150 are between and isolate semiconductor structures 130 and may be such a low-K dielectric.

Channel structures 130 may be any suitable structure of any suitable material(s), such as a semiconductor material. Examples of semiconductor material include silicon (Si), germanium (Ge), silicon germanium (SiGe), a III-V alloy material (e.g., gallium arsenide (GaAs) or gallium nitride (GaN)), a silicon carbide (e.g., SiC), etc., or a combination thereof. In some embodiments, channel structures 130 include a monocrystalline semiconductor material, such as monocrystalline silicon, germanium, a III-V alloy material, etc., responsive to strain engineering. Channel structures 130 may include other materials.

Channel structures 130 may be or include planar or nonplanar structures. Channel structures 130 may be or include one or more fins or nanoribbons. Channel structures 130 have a first width W₁ between floating structures 140 and a second width W₂ greater than width W₁ outside floating structures 140. For example, transistors 110, 120 may be FinFETs (field effect transistors). In some such embodiments, channel structures 130 may have channel regions 132 with three fins in width W₂ and transistors 120 (outside floating structures 140), and channel structures 130 may have channel regions 131 with two fins in width W₁ and transistors 110 (between floating structures 140).

Channel structures 130 may be (or be within) a doped semiconductor region having a desired conductivity type (such as n- or p-type conductivity), such as a diffusion well. The semiconductor region may be doped at any suitable dopant concentration. Channel structures 130 may be of either conductivity type. In many embodiments, channel structures 130 have alternating conductivity type. In the exemplary embodiment, channel structures 130A, 130C (and transistors 110A, 110C, 120A, 120C and their channel regions 131A, 131C, 132A, 132C) have p-type conductivity, and channel structure 130B has n-type conductivity (as do transistors 110B. 120B and their channel regions 131B, 132B). Although shown with ends under floating structures 140, one or more channel structures 130A, 130B, 130C extend beyond the edges of FIG. 1A in many embodiments and compromise many more channel regions 131, 132.

Channel regions 131, 132 are portions of channel structures 130 in transistors 110, 120 that couple respective drain structures 116, 126 to source structures 117, 127. Channel regions 131, 132 are between and mechanically couple drain structures 116, 126 and source structures 117, 127. When transistors 110, 120 conduct, channel regions 131, 132 electrically couple drain structures 116, 126 and source structures 117, 127.

Transistors 110 have gate structures 115 between drain and source structures 116, 117, and transistors 120 have gate structures 125 between drain and source structures 126, 127. Gate structures 115, 125 may be substantially similar, e.g., the same, but for gate structure 115 coupling to the narrower channel region 131 of transistor 110 and gate structure 125 coupling to the wider channel region 132 of transistor 120. Gate structures 115, 125 control the conduction of channel regions 131, 132 and transistors 110, 120. Gate structures 115, 125 may include one or more dielectric layers over channel regions 131, 132 and one or more conductive layers over the one or more dielectric layers. Conductive layers in gate structures 115, 125 may include liner or seed layers, one or more work function layers, and bulk or fill metal. Gate structures 115 of some transistors (such as transistors 110A, 110B) are coupled, e.g., in inverter configurations, as are gate structures 125 (of transistors 120A, 120B).

Drain structures 116, 126 and source structures 117, 127 may be or include metallization that contacts either end of channel regions 131, 132. Drain and source structures 116, 117, 126, 127 may include multiple metals in a stack, such as liner or seed layers around a bulk or fill metal. Drain structures 116, 126 and source structures 117, 127 may be or include heavily doped semiconductor regions that contacts either end of channel regions 131, 132. Drain structures 116, 126 may be substantially similar, e.g., the same, but for drain structure 116 coupling to the narrower channel region 131 of transistor 110 and drain structure 126 coupling to the wider channel region 132 of transistor 120. Source structures 117, 127 may be substantially similar, e.g., the same, but for source structure 117 coupling to the narrower channel region 131 of transistor 110 and source structure 127 coupling to the wider channel region 132 of transistor 120. Contacts 160 are electrically conductive connections, such as metal vias, that couple transistors 110, 120 to electrical interconnects (not shown).

FIG. 1B shows a cross-sectional profile view B-B′ through conductive floating structure 140 and multiple channel structures 130 in one possible embodiment of FIG. 1A. Other possible embodiments of FIG. 1A may have different structures and different cross-sections. In the exemplary embodiment of FIG. 1B, channel structures 130 include fins 133. Floating structures 140 over channel structures 130 may have a structure similar to (e.g., substantially the same as) a gate structure 115, 125, but without contacts 160 or other electrically conductive connections to electrical interconnects (not shown; e.g., metal 0 (M0), metal 1 (M1), etc., or other interconnect layers). For example, conductive floating structures 140 may be coupled to, but electrically insulated or isolated from, semiconductor structures 130 by dielectric material layer 145, as shown in FIG. 1B. Floating structures 140 are coupled to semiconductor structures 130 between channel regions 131,132. Conductive floating structure 140 is a stripe of material between, and adjacent to, a first sidewall 136 of semiconductor structure 130A and a second sidewall 137 of semiconductor structure 130B. Conductive floating structure 140 is a stripe of material that spans over isolation structure 150 between semiconductor structures 130A, 130B. Conductive floating structure 140 spans semiconductor structures 130A, 130B in the y direction.

Floating structures 140 may induce a mechanical strain on or in channel structures 130 (and channel regions 131, 132) due to different material characteristics of structures 140 relative to, e.g., isolation structure 150 between semiconductor structures 130A, 130B, 130C. The material(s) of structures 140 (e.g., gate metals) may exert force(s) on channel structures 130 (e.g., tensile or compressive forces) different from force(s) exerted by isolation structure 150 (for example, or other materials). The strain resultant from the deployment of structures 140 may effect a beneficial shift of threshold voltage(s) Vₜₕ, e.g., for transistors 110, 120 along conductive floating structure 140.

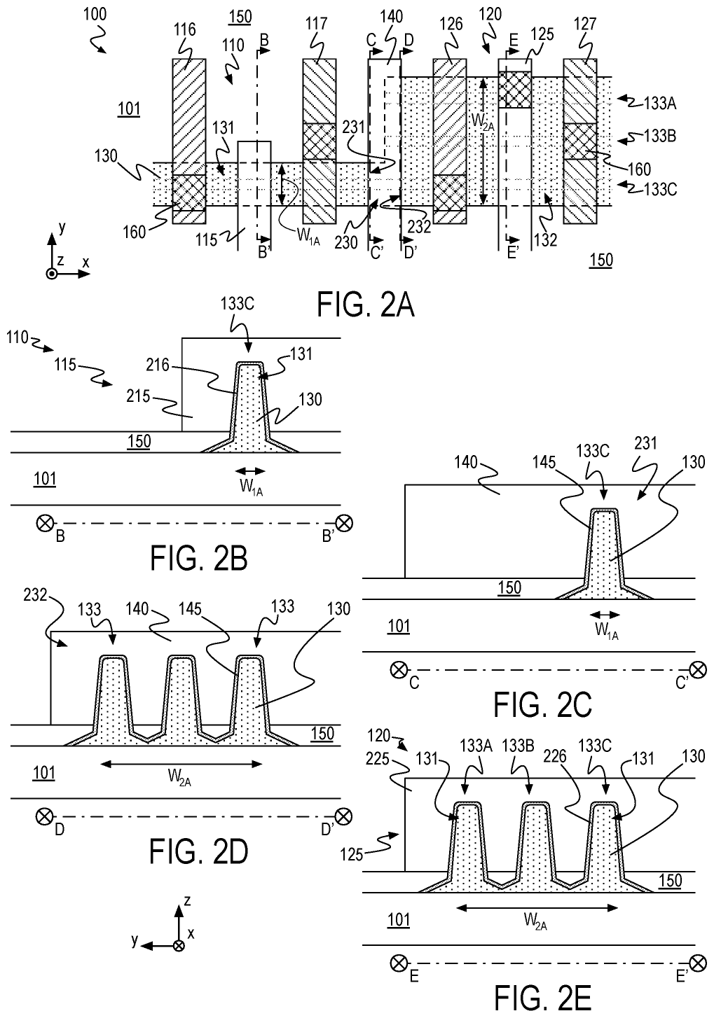

FIGS. 2A, 2B, 2C, 2D, and 2E illustrate plan and cross-sectional profile views of IC device 100 having conductive floating structure 140 over, and coupled to, channel regions 131, 132 within fins 133 of semiconductor channel structure 130, in accordance with some embodiments. FIGS. 2B-2E are cross-sectional profile views of device 100 taken at the locations shown in FIG. 2A (e.g., FIG. 2B at cross-section B-B′, FIG. 2C at cross-section C-C′, etc.). FIG. 2A shows a portion of semiconductor structure 130, which includes fins 133A, 133B, 133C. Semiconductor structure 130 includes multiple fins 133A, 133B, 133C within channel region 132 and width W₂. Semiconductor structure 130 includes channel region 131 within single fin 133C and with width W₁. Fins 133A, 133B are not within channel region 131 and width W₁. Isolation structure 150 is on both sides of channel structure 130.

A transition portion 230 or transition section of semiconductor structure 130 is under, and covered by, floating structure 140 and between channel regions 131, 132 (and between transistors 110, 120). Transition portion 230 is a section of semiconductor structure 130 where structure 130 transitions from one of widths W₁, W₂ to the other. Transition portion 230 may be encapsulated by floating structure 140 and dielectric material layer 145. Transition portion 230 has the first width W₁ on a first side 231 adjacent and coupled to channel region 131 and transistor 110, and transition portion 230 has second width W₂ on a second side 232 adjacent and coupled to channel region 132 and transistor 120. Floating structure 140 covers transition portion 230 of channel structure 130.

FIG. 2B illustrates a cross-sectional profile view B-B′ of gate structure 115 (which includes a gate metal 215 over a gate dielectric layer 216) over a single fin 133C (of channel structure 130). Fin 133C and channel structure 130 include channel region 131. At view B-B′, channel region 131 of semiconductor structure 130 (and transistor 110) has only a width W_{1A}.

Gate metal 215 is coupled to fin 133C of channel structure 130 by gate dielectric layer 216, which may be similar to (e.g., the same as) dielectric material layer 145 (which couples and insulates floating structure 140 from semiconductor structure 130). Gate dielectric layer 216 provides electrical insulation between channel region 131 and gate metal 215. Gate dielectric layer 216 may have more than one layer. Gate dielectric layer 216 may be of any suitable material(s). The one or more layers of gate dielectric layer 216 may include a silicon oxide, silicon dioxide (SiO₂), a silicon oxynitride, etc. Advantageously, gate dielectric layer 216 includes a high-permittivity (“high-K”) dielectric (for example, having a dielectric constant over 6). A high-k dielectric material may include one or more of various elements, such as hafnium, silicon, oxygen, titanium, tantalum, lanthanum, aluminum, zirconium, barium, strontium, yttrium, lead, scandium, niobium, and zinc. Gate dielectric layer 216 may include a dopant, e.g., for elevated permittivity. Examples of high-k materials that may be used in gate dielectric layer 216 include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, etc.

FIG. 2C shows a cross-sectional profile view C-C′ of side 231 of transition portion 230 with floating structure 140 over transition portion 230 of semiconductor structure 130. At view C-C′, semiconductor structure 130 and transition portion 230 has only a width W_{1A}. Dielectric material layer 145 is over fin 133C of channel structure 130 at side 231 between channel regions 131, 132. Conductive floating structure 140 spans over isolation structure 150.

FIG. 2D illustrates a cross-sectional profile view D-D′ of side 232 of transition portion 230 with floating structure 140 over transition portion 230 of semiconductor structure 130. At view D-D′, semiconductor structure 130 and transition portion 230 has width W_{2A}. Dielectric material layer 145 is over multiple fins 133 of channel structure 130 at side 232 between channel regions 131, 132. Conductive floating structure 140 spans over isolation structure 150.

FIG. 2E shows a cross-sectional profile view E-E′ of gate structure 125 (which includes a gate metal 225 over a gate dielectric layer 226) over multiple fins 133 (e.g., fins 133A, 133B, 133C) of channel structure 130. Fins 133 and channel structure 130 include channel region 132. At view E-E′, channel region 132 of semiconductor structure 130 (and transistor 120) has width W_{2A}. Fin 133C is also within width W_{1A}. Fins 133A, 133B are within width W_{2A}, but outside width W_{1A}.

Gate metal 225 is coupled to fins 133 of channel structure 130 by gate dielectric layer 226, which may be similar to (e.g., the same as) dielectric material layer 145. Gate dielectric layer 226 provides electrical insulation between channel region 132 and gate metal 225. Floating structure 140 and dielectric material layer 145 may advantageously be formed concurrently with gate structures 115, 125, which may be similar to (or the same as) floating structure 140, but for the presence (or not) of contacts 160 and location over (or not) channel regions 131, 132. Dielectric material layer 145 may include any of the materials in the descriptions of gate dielectric layers 216, 226. Gate dielectric layers 216, 226 may be similar (e.g., the same) but for their deployment in different transistors 110, 120. Dielectric material layer 145 may be very thin, for example, as thin or thinner than gate dielectric layers 216, 226. In some embodiments, dielectric material layer 145 is less than 5 nm thick.

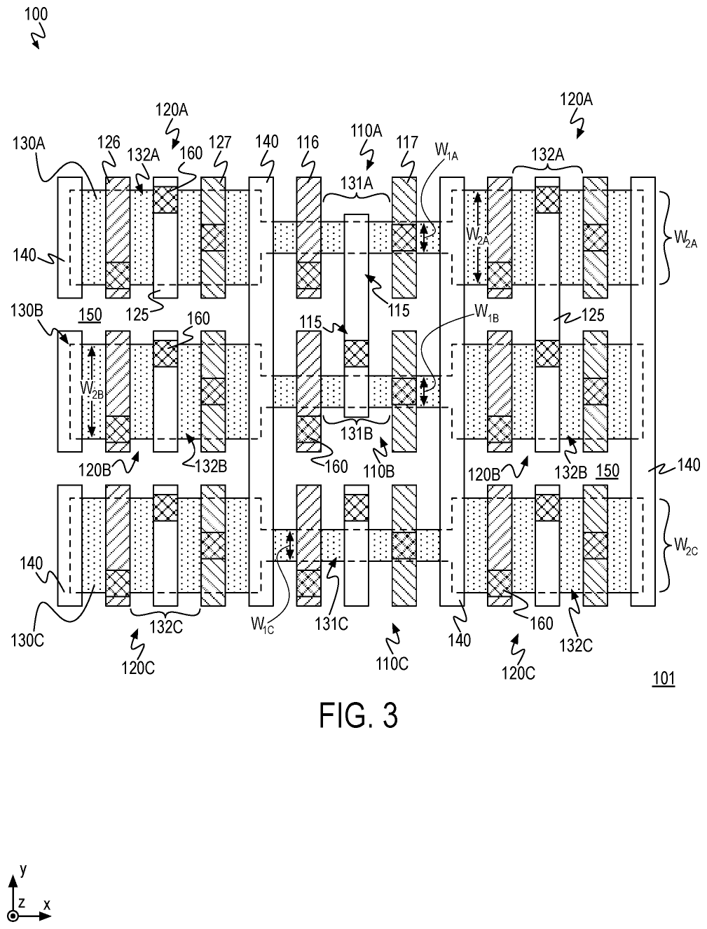

FIG. 3 illustrates a plan view of an IC device having conductive floating structures 140 over an array of transistors 110, 120 and shared semiconductor channel structures 130 with channel regions 131, 132 of varying widths W₁, W₂, in accordance with some embodiments. The embodiments of FIG. 3 may be substantially as that described at FIG. 1A. Notably, within any given channel structure 130, channel regions 131 are centered and aligned with channel regions 132. Channel regions 131, 132 within given channel structures 130 are coaxial, symmetric about a same axis or centerline.

Channel structures 130 may include nanoribbons (e.g., in a stack of nanoribbons), and a centerline of channel region 131 is colinear with a centerline of channel region 132. Hence, channel regions 131, 132 are substantially symmetrical about the nanoribbon centerline. In some embodiments, device 100 includes stacks of nanoribbons, and each of the stacks of nanoribbons includes one of structures 130. Maintaining a shared centerline for nanoribbon channel regions 131, 132 may be advantageous, for example, to maximize symmetry between transistors, e.g., within a local circuit, and/or minimize any difference in effective length of contact metallization or other conduction paths between devices. Channel regions 131, 132 situated coaxially may provide optimal performance, e.g., even or balanced current densities or distributions between drain and source structures 116, 117 through width W₁ of channel regions 131, 132. Centered or coaxial channel regions 131 may maximize isolation (e.g., a maximum width of isolation structures 150) between adjacent channel regions 131 (or channel regions 131, 132). In some embodiments, channel regions 131 are adjacent channel regions 132 of adjacent channel structures 130.

In some embodiments, semiconductor structure 130 includes ultrathin materials, e.g., two-dimensional (2D) materials, such as black phosphorous or a transition-metal dichalcogenide (TMD) material. TMDs are compounds that include chalcogenides (e.g., any of sulfur(S), selenium (Se), or tellurium (Te)) and transition metals, which are defined to include any element in the d-block of the periodic table, i.e., group 3 through group 12, and any element in the f-block of the periodic table, i.e., “inner transition metals.” Dichalcogenides include twice as many chalcogenides as transition metal atoms. TMDs can be 2D materials, e.g., forming monolayers of semiconductor materials. In some embodiments, semiconductor structure 130 includes molybdenum (Mo) or tungsten (W). In some such embodiments, semiconductor structure 130 includes MoS₂, MoSe₂, WS₂, or WSe₂. A semiconductor structure 130 may utilize other compositions. In some embodiments, semiconductor structure 130 may include one or more dopants such as another metal or a nonmetallic dopant, such as nitrogen, oxygen, hydrogen, fluorine, chlorine, silicon, or germanium, that may introduce electron vacancies or oxygen vacancies.

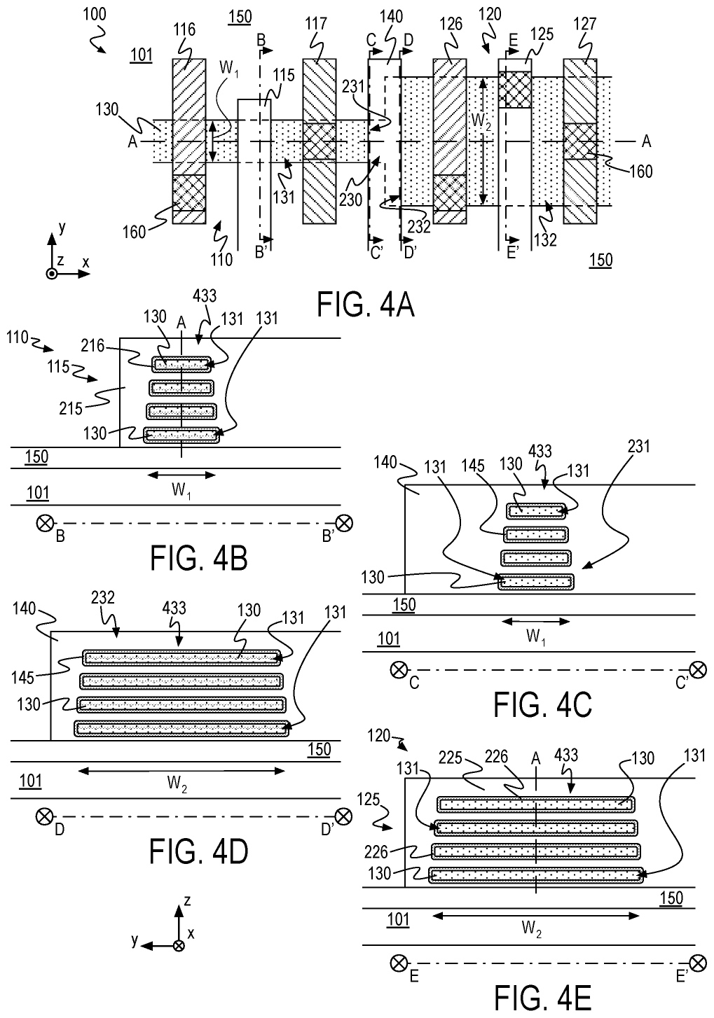

FIGS. 4A, 4B, 4C, 4D, and 4E illustrate plan and cross-sectional profile views of IC device 100 having conductive floating structure 140 over, and coupled to, channel regions 131, 132 within nanoribbons 433 of semiconductor channel structure 130, in accordance with some embodiments. FIGS. 4A, 4B, 4C, 4D, and 4E may illustrate exemplary portions of the embodiments shown in FIG. 3. FIGS. 4B-4E are cross-sectional profile views of device 100 taken at the locations shown in FIG. 4A (e.g., FIG. 4B at cross-section B-B′, FIG. 4C at cross-section C-C′, etc.). FIG. 4A shows a portion of exemplary semiconductor structure 130, which includes a stack of nanoribbons 433. Channel regions 132 within nanoribbons 433 and semiconductor structure 130 have width W₂. A widest nanoribbon 433 has width W₂ at channel region 132. Channel regions 131 are narrower within nanoribbons 433 and semiconductor structure 130 and have width W₁ (less than width W₂). A widest nanoribbon 433 has width W₁ at channel region 131. Isolation structure 150 is on both sides of channel structure 130.

In some embodiments, channel structure 130 is a nanoribbon, and channel structure 130 and channel regions 131, 132 are centered on an axis A that bisects structure 130 and regions 131, 132, as well as widths W₁, W₂. In some embodiments, channel structure 130 includes a stack of nanoribbons 433, the stack of nanoribbons 433 includes channel regions 131, 132, and channel structure 130 and channel regions 131, 132 are centered on a plane of symmetry A (showing as an axis A in FIG. 4A) that bisects structure 130 and regions 131, 132, as well as widths W₁, W₂. Channel region 131 has a plane of symmetry (e.g., an x-z plane) at axis A (e.g., a line in an x-y plane, extending in the x direction), channel region 132 has a plane of symmetry (e.g., an x-z plane) at axis A, and the planes of symmetry are aligned at axis A. Widths W₁, W₂ are centered on axis A.

Transition portion 230 of semiconductor structure 130 is under, and covered by, floating structure 140 and between channel regions 131, 132 (and between transistors 110, 120). Transition portion 230 may be encapsulated by floating structure 140 and dielectric material layer 145. Transition portion 230 has the first width W₁ on a first side 231 adjacent and coupled to channel region 131 and transistor 110, and transition portion 230 has second width W₂ on a second side 232 adjacent and coupled to channel region 132 and transistor 120. Floating structure 140 covers transition portion 230 of channel structure 130.

FIG. 4B illustrates a cross-sectional profile view B-B′ of gate structure 115, including gate metal 215 and dielectric layer 216) over a stack of nanoribbons 433 (of channel structure 130). The stack of nanoribbons 433 and channel structure 130 include channel region 131. At view B-B′, channel region 131 of semiconductor structure 130 has only a width W_{1A}. Gate metal 215 is coupled to nanoribbons 433 of channel structure 130 by gate dielectric layer 216.

FIG. 4C shows a cross-sectional profile view C-C′ of side 231 of transition portion 230 with floating structure 140 over transition portion 230 of semiconductor structure 130. At view C-C′, semiconductor structure 130 and transition portion 230 has only a width W_{1A}. Dielectric material layer 145 is over the stack of nanoribbons 433 of channel structure 130 at side 231 between channel regions 131, 132. Conductive floating structure 140 spans over isolation structure 150.

FIG. 4D illustrates a cross-sectional profile view D-D′ of side 232 of transition portion 230 with floating structure 140 over transition portion 230 of semiconductor structure 130. At view D-D′, semiconductor structure 130 and transition portion 230 has a larger width W_{2A}. Dielectric material layer 145 is over a wider stack of nanoribbons 433 of channel structure 130 at side 232 between channel regions 131, 132. Conductive floating structure 140 spans over isolation structure 150.

FIG. 4E shows a cross-sectional profile view E-E′ of gate structure 125, including gate metal 225 and dielectric layer 226 over nanoribbons 433 of channel structure 130. Nanoribbons 433 and channel structure 130 include channel region 132. At view E-E′, channel region 132 of semiconductor structure 130 has width W_{2A}.

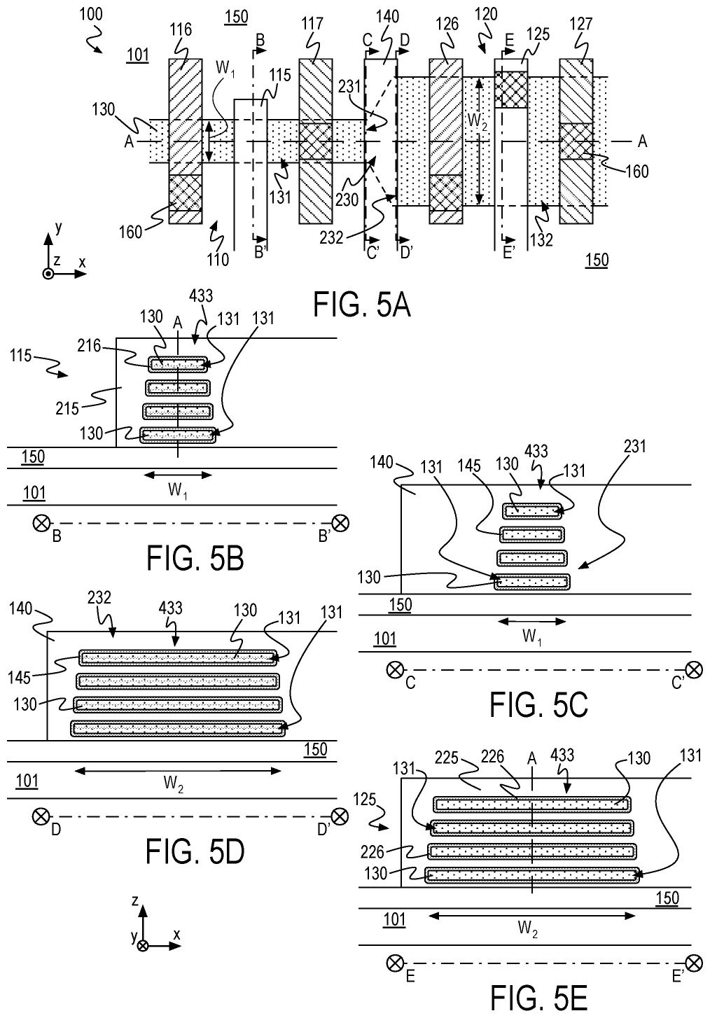

FIGS. 5A, 5B, 5C, 5D, and 5E illustrate plan and cross-sectional profile views of IC device 100 having conductive floating structure 140 over, and coupled to, channel regions 131, 132 within nanoribbons 433 of semiconductor channel structure 130, in accordance with some embodiments. FIGS. 5B-5E are cross-sectional profile views of device 100 taken at the locations shown in FIG. 5A (e.g., FIG. 5B at cross-section B-B′, FIG. 5C at cross-section C-C′, etc.). FIG. 5A shows a portion of semiconductor structure 130, including a stack of nanoribbons 433 similar to the nanoribbons 433 illustrated in FIG. 4A. Notably, FIG. 5A illustrates an alternate transition portion 230 with less abrupt width transitions between widths W₁, W₂ of channel regions 131, 132. External to floating structure 140, nanoribbons 433 and semiconductor channel structure 130 may appear similar or the same (e.g., as in FIG. 4A).

Transition portion 230 of semiconductor structure 130 is under, and covered by, floating structure 140 and between channel regions 131, 132. Transition portion 230 has width W₁ on side 231 and width W₂ on side 232. At view B-B′ of FIG. 5B, channel region 131 of semiconductor structure 130 has only a width W_{1A}. At view C-C′ of FIG. 5C, at side 231 between channel regions 131, 132, semiconductor structure 130 and transition portion 230 has only a width W_{1A}. At view D-D′ of FIG. 5D, at side 232 between channel regions 131, 132, semiconductor structure 130 and transition portion 230 has a larger width W_{2A}. At view E-E′ of FIG. 5E, channel region 132 of semiconductor structure 130 has width W_{2A}.

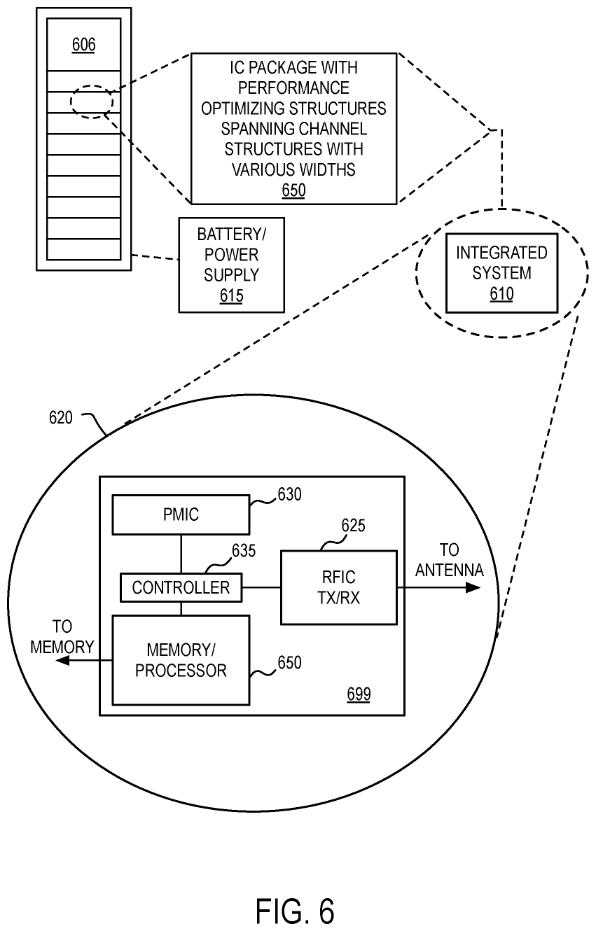

FIG. 6 illustrates a diagram of an example data server machine 606 employing an IC device having channel structures with multiple widths and having performance-optimizing structures spanning the channel structures, in accordance with some embodiments. Server machine 606 may be any commercial server, for example, including any number of high-performance computing platforms disposed within a rack and networked together for electronic data processing, which in the exemplary embodiment includes one or more devices 650 having performance-optimizing structures spanning channel structures with multiple widths.

Also as shown, server machine 606 includes a battery and/or power supply 615 to provide power to devices 650, and to provide, in some embodiments, power delivery functions such as power regulation. Devices 650 may be deployed as part of a package-level integrated system 610. Integrated system 610 is further illustrated in the expanded view 620. In the exemplary embodiment, devices 650 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 650 is a microprocessor including a static RAM (SRAM) cache memory. As shown, device 650 may be an IC device having performance-optimizing structures spanning channel structures with multiple widths, as discussed herein. Device 650 may be further coupled to (e.g., communicatively coupled to) a board, an interposer, or a substrate 699 along with, one or more of a power management IC (PMIC) 630, RF (wireless) IC (RFIC) 625 including a wideband RF (wireless) transmitter and/or receiver (TX/RX) (e.g., including a digital baseband and an analog front end module further includes a power amplifier on a transmit path and a low noise amplifier on a receive path), and a controller 635 thereof. In some embodiments, RFIC 625, PMIC 630, controller 635, and device 650 include performance-optimizing structures spanning channel structures with multiple widths.

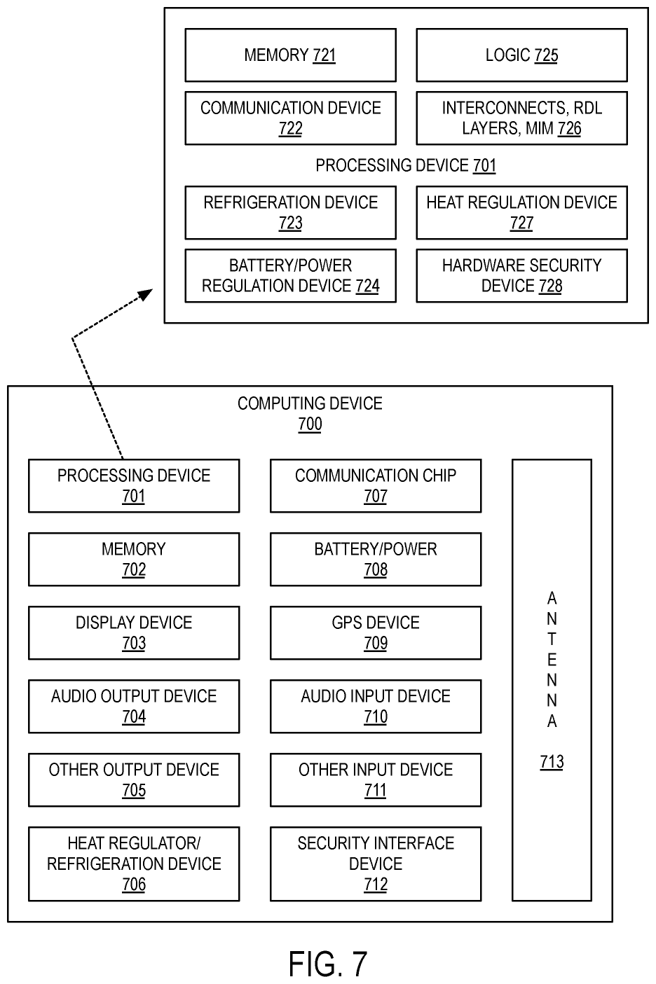

FIG. 7 is a block diagram of an example computing device 700, in accordance with some embodiments. For example, one or more components of computing device 700 may include any of the devices or structures discussed herein. A number of components are illustrated in FIG. 7 as being included in computing device 700, but any one or more of these components may be omitted or duplicated, as suitable for the application. In some embodiments, some or all of the components included in computing device 700 may be attached to one or more printed circuit boards (e.g., a motherboard). In some embodiments, various ones of these components may be fabricated onto a single system-on-a-chip (SoC) die. Additionally, in various embodiments, computing device 700 may not include one or more of the components illustrated in FIG. 7, but computing device 700 may include interface circuitry for coupling to the one or more components. For example, computing device 700 may not include a display device 703, but may include display device interface circuitry (e.g., a connector and driver circuitry) to which display device 703 may be coupled. In another set of examples, computing device 700 may not include an audio output device 704, other output device 705, global positioning system (GPS) device 709, audio input device 710, or other input device 711, but may include audio output device interface circuitry, other output device interface circuitry, GPS device interface circuitry, audio input device interface circuitry, audio input device interface circuitry, to which audio output device 704, other output device 705, GPS device 709, audio input device 710, or other input device 711 may be coupled.

Computing device 700 may include a processing device 701 (e.g., one or more processing devices). As used herein, the term “processing device” or “processor” indicates a device that processes electronic data from registers and/or memory to transform that electronic data into other electronic data that may be stored in registers and/or memory. Processing device 701 may include a memory 721, a communication device 722, a refrigeration device 723, a battery/power regulation device 724, logic 725, interconnects 726 (i.e., optionally including redistribution layers (RDL) or metal-insulator-metal (MIM) devices), a heat regulation device 727, and a hardware security device 728.

Processing device 701 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 700 may include a memory 702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 702 includes memory that shares a die with processing device 701. This memory may be used as cache memory and may include embedded dynamic random-access memory (eDRAM) or spin transfer torque magnetic random-access memory (STT-MRAM).

Computing device 700 may include a heat regulation/refrigeration device 706. Heat regulation/refrigeration device 706 may maintain processing device 701 (and/or other components of computing device 700) at a predetermined low temperature during operation.

In some embodiments, computing device 700 may include a communication chip 707 (e.g., one or more communication chips). For example, the communication chip 707 may be configured for managing wireless communications for the transfer of data to and from computing device 700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 707 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 707 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 707 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 707 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 707 may operate in accordance with other wireless protocols in other embodiments. Computing device 700 may include an antenna 713 to facilitate wireless communications and/or to receive other wireless communications (such as AM or FM radio transmissions).

In some embodiments, communication chip 707 may manage wired communications, such as electrical, optical, or any other suitable communication protocols (e.g., the Ethernet). As noted above, communication chip 707 may include multiple communication chips. For instance, a first communication chip 707 may be dedicated to shorter-range wireless communications such as Wi-Fi or Bluetooth, and a second communication chip 707 may be dedicated to longer-range wireless communications such as GPS, EDGE, GPRS, CDMA, WiMAX, LTE, EV-DO, or others. In some embodiments, a first communication chip 707 may be dedicated to wireless communications, and a second communication chip 707 may be dedicated to wired communications.

Computing device 700 may include battery/power circuitry 708. Battery/power circuitry 708 may include one or more energy storage devices (e.g., batteries or capacitors) and/or circuitry for coupling components of computing device 700 to an energy source separate from computing device 700 (e.g., AC line power).

Computing device 700 may include a display device 703 (or corresponding interface circuitry, as discussed above). Display device 703 may include any visual indicators, such as a heads-up display, a computer monitor, a projector, a touchscreen display, a liquid crystal display (LCD), a light-emitting diode display, or a flat panel display, for example.

Computing device 700 may include an audio output device 704 (or corresponding interface circuitry, as discussed above). Audio output device 704 may include any device that generates an audible indicator, such as speakers, headsets, or earbuds, for example.

Computing device 700 may include an audio input device 710 (or corresponding interface circuitry, as discussed above). Audio input device 710 may include any device that generates a signal representative of a sound, such as microphones, microphone arrays, or digital instruments (e.g., instruments having a musical instrument digital interface (MIDI) output).

Computing device 700 may include a GPS device 709 (or corresponding interface circuitry, as discussed above). GPS device 709 may be in communication with a satellite-based system and may receive a location of computing device 700, as known in the art.

Computing device 700 may include other output device 705 (or corresponding interface circuitry, as discussed above). Examples of the other output device 705 may include an audio codec, a video codec, a printer, a wired or wireless transmitter for providing information to other devices, or an additional storage device.

Computing device 700 may include other input device 711 (or corresponding interface circuitry, as discussed above). Examples of the other input device 711 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 700 may include a security interface device 712. Security interface device 712 may include any device that provides security measures for computing device 700 such as intrusion detection, biometric validation, security encode or decode, access list management, malware detection, or spyware detection.

Computing device 700, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-7. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a first transistor, including a first channel region with a first width, and a second transistor, including a second channel region with a second width greater than the first width, a third transistor, including a third channel region with a third width, and a fourth transistor, including a fourth channel region with a fourth width greater than the third width, first and second semiconductor structures, extending in a first direction, wherein the first semiconductor structure includes the first and second channel regions and a first sidewall therebetween, and the second semiconductor structure includes the third and fourth channel regions and a second sidewall therebetween, and a stripe of material between and adjacent the first and second sidewalls, spanning the first and second semiconductor structures in a second direction perpendicular to the first direction.

In one or more second embodiments, further to the first embodiments, a transition portion of the first semiconductor structure is under the stripe of material and between the first and second channel regions, the transition portion has the first width on a first side adjacent the first channel region, and the transition portion has the second width on a second side adjacent the second channel region.

In one or more third embodiments, further to the first or second embodiments, the stripe of material is a floating conductor coupled to the first and second semiconductor structures by a dielectric material layer.

In one or more fourth embodiments, further to the first through third embodiments, the stripe of material spans over an isolation structure between the first and second semiconductor structures.

In one or more fifth embodiments, further to the first through fourth embodiments, the first transistor has a first threshold voltage, the second transistor has a second threshold voltage, and the first and second threshold voltages are substantially equal.

In one or more sixth embodiments, further to the first through fifth embodiments, the first and second transistors have p-type conductivity, and the third and fourth transistors have n-type conductivity.

In one or more seventh embodiments, further to the first through sixth embodiments, the first semiconductor structure includes a plurality of fins within the second width, a first of the plurality of fins is within the first width, and a second of the plurality of fins is outside the first width.

In one or more eighth embodiments, further to the first through seventh embodiments, the first semiconductor structure includes a nanoribbon, the nanoribbon has the first width at the first channel region, and the nanoribbon has the second width at the second channel region.

In one or more ninth embodiments, further to the first through eighth embodiments, an axis of the nanoribbon bisects the first and second widths.

In one or more tenth embodiments, further to the first through ninth embodiments, the first semiconductor structure includes a stack of nanoribbons, and the stack of nanoribbons includes the first and second channel regions.

In one or more eleventh embodiments, an apparatus includes a plurality of channel structures, extending in a first direction, wherein individual ones of the channel structures include adjacent first and second channel regions, the first channel regions having a first width less than a second width of the second channel regions, an array of transistors including pluralities of first and second transistors, wherein the first transistors include the first channel regions, and the second transistors include the second channel regions, and a conductive floating structure, extending in a second direction and coupling the plurality of channel structures and between the first and second transistors, wherein the floating structure covers a transition section of an individual one of the channel structures, the transition section having the first width on a first side coupled to a corresponding one of the first transistors and having the second width on a second side coupled to a corresponding one of the second transistors.

In one or more twelfth embodiments, further to the eleventh embodiments, a dielectric material couples the floating structure and individual ones of the channel structures.

In one or more thirteenth embodiments, further to the eleventh or twelfth embodiments, individual ones of the first and second channel regions corresponding to a first channel structure are of a first conductivity type, and individual ones of the first and second channel regions corresponding to an adjacent second channel structure are of a second conductivity type.

In one or more fourteenth embodiments, further to the eleventh through thirteenth embodiments, the first channel structure includes a stack of nanoribbons having the second width within an individual one of the second transistors and having the first width within an individual one of the first transistors.

In one or more fifteenth embodiments, further to the eleventh through fourteenth embodiments, a first plane of symmetry of an individual one of the first channel regions is substantially aligned with a second plane of symmetry of an individual one of the second channel regions.

In one or more sixteenth embodiments, further to the eleventh through fifteenth embodiments, a first channel structure includes first and second fins within the second width, the first fin is within the first width, and the second fin is not in the first width.

In one or more seventeenth embodiments, an apparatus includes first, second, and third pluralities of fins or nanoribbons extending in a first direction, the first plurality between the second and third pluralities and including a channel region, first and second floating conductors spanning between the second and third pluralities in a second direction, wherein the first plurality has a first width between the first and second floating conductors and a second width greater than the first width outside the first and second floating conductors, and a transistor, including the channel region.

In one or more eighteenth embodiments, further to the seventeenth embodiments, the transistor is a first transistor, the channel region is a first channel region, and the first plurality of fins or nanoribbons further includes second and third channel regions having the second width in second and third transistors, wherein the first floating conductor is between the first and second channel regions, the second floating structure is between the first and third channel regions.

In one or more nineteenth embodiments, further to the seventeenth or eighteenth embodiments, the first plurality of fins or nanoribbons are coupled to the first and second floating conductors by a dielectric material layer.

In one or more twentieth embodiments, further to the seventeenth through nineteenth embodiments, the first or second floating conductor is adjacent and between a first sidewall of the first plurality of fins or nanoribbons and a second sidewall of the second or third pluralities of fins or nanoribbons.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a first transistor, comprising a first channel region with a first width, and a second transistor, comprising a second channel region with a second width greater than the first width;
a third transistor, comprising a third channel region with a third width, and a fourth transistor, comprising a fourth channel region with a fourth width greater than the third width;
first and second semiconductor structures, extending in a first direction, wherein the first semiconductor structure comprises the first and second channel regions and a first sidewall therebetween, and the second semiconductor structure comprises the third and fourth channel regions and a second sidewall therebetween; and
a stripe of material between and adjacent the first and second sidewalls, spanning the first and second semiconductor structures in a second direction perpendicular to the first direction.

2. The apparatus of claim 1, wherein:
a transition portion of the first semiconductor structure is under the stripe of material and between the first and second channel regions;
the transition portion has the first width on a first side adjacent the first channel region; and
the transition portion has the second width on a second side adjacent the second channel region.

3. The apparatus of claim 1, wherein the stripe of material is a floating conductor coupled to the first and second semiconductor structures by a dielectric material layer.

4. The apparatus of claim 1, wherein the stripe of material spans over an isolation structure between the first and second semiconductor structures.

5. The apparatus of claim 1, wherein the first transistor has a first threshold voltage, the second transistor has a second threshold voltage, and the first and second threshold voltages are substantially equal.

6. The apparatus of claim 1, wherein the first and second transistors have p-type conductivity, and the third and fourth transistors have n-type conductivity.

7. The apparatus of claim 1, wherein the first semiconductor structure comprises a plurality of fins within the second width, a first of the plurality of fins is within the first width, and a second of the plurality of fins is outside the first width.

8. The apparatus of claim 1, wherein:
the first semiconductor structure comprises a nanoribbon;
the nanoribbon has the first width at the first channel region; and
the nanoribbon has the second width at the second channel region.

9. The apparatus of claim 8, wherein an axis of the nanoribbon bisects the first and second widths.

10. The apparatus of claim 8, wherein the first semiconductor structure comprises a stack of nanoribbons, and the stack of nanoribbons comprises the first and second channel regions.

11. An apparatus, comprising:
a plurality of channel structures, extending in a first direction, wherein individual ones of the channel structures comprise adjacent first and second channel regions, the first channel regions having a first width less than a second width of the second channel regions;
an array of transistors comprising pluralities of first and second transistors, wherein the first transistors comprise the first channel regions, and the second transistors comprise the second channel regions; and
a conductive floating structure, extending in a second direction and coupling the plurality of channel structures and between the first and second transistors, wherein the floating structure covers a transition section of an individual one of the channel structures, the transition section having the first width on a first side coupled to a corresponding one of the first transistors and having the second width on a second side coupled to a corresponding one of the second transistors.

12. The apparatus of claim 11, wherein a dielectric material couples the floating structure and individual ones of the channel structures.

13. The apparatus of claim 12, wherein individual ones of the first and second channel regions corresponding to a first channel structure are of a first conductivity type, and individual ones of the first and second channel regions corresponding to an adjacent second channel structure are of a second conductivity type.

14. The apparatus of claim 13, wherein the first channel structure comprises a stack of nanoribbons having the second width within an individual one of the second transistors and having the first width within an individual one of the first transistors.

15. The apparatus of claim 14, wherein a first plane of symmetry of an individual one of the first channel regions is substantially aligned with a second plane of symmetry of an individual one of the second channel regions.

16. The apparatus of claim 13, wherein the first channel structure comprises first and second fins within the second width, the first fin is within the first width, and the second fin is not in the first width.

17. An apparatus, comprising:
first, second, and third pluralities of fins or nanoribbons extending in a first direction, the first plurality between the second and third pluralities and comprising a channel region;
first and second floating conductors spanning between the second and third pluralities in a second direction, wherein the first plurality has a first width between the first and second floating conductors and a second width greater than the first width outside the first and second floating conductors; and
a transistor, comprising the channel region.

18. The apparatus of claim 17, wherein the transistor is a first transistor, the channel region is a first channel region, and the first plurality of fins or nanoribbons further comprises second and third channel regions having the second width in second and third transistors, wherein the first floating conductor is between the first and second channel regions, the second floating structure is between the first and third channel regions.

19. The apparatus of claim 18, wherein the first plurality of fins or nanoribbons are coupled to the first and second floating conductors by a dielectric material layer.

20. The apparatus of claim 19, wherein the first or second floating conductor is adjacent and between a first sidewall of the first plurality of fins or nanoribbons and a second sidewall of the second or third pluralities of fins or nanoribbons.
